(19) United States
(12) Patent Application Publication
(10) Pub. No.: US 2012/0168752 A1
(43) Pub. Date: Jul. 5, 2012

(54) TESTKEY STRUCTURE, CHIP PACKAGING STRUCTURE, AND METHOD FOR FABRICATING THE SAME

(76) Inventor: Kun-Tai Wu, Zhubei City (TW)

(21) Appl. No.: 12/981,777

(22) Filed: Dec. 30, 2010

(51) Int. Cl. H01L 23/482; H01L 21/71; H01L 21/78; H01L 23/544

(52) U.S. Cl. 257/48; 257/773; 438/612; 438/462; 257/E23.179; 257/E23.012; 257/E21.536; 257/E21.599

(57) ABSTRACT

The invention provides a testkey structure for testing a chip. The testkey structure includes a metal pad and a first groove, wherein the first groove is disposed on the metal pad. The first groove is located between a first signal lead and a second signal lead of the chip. According to the first groove, the first signal lead and the second signal lead could be separated from each other to prevent the first signal lead and the second signal lead from shorting.

### BACKGROUND OF THE INVENTION

1. Field of the Invention

The invention relates to a testkey structure and a chip packaging structure, and in particular, to a testkey structure and a chip packaging structure capable of preventing the short condition of the chip signal leads generated because the testkey is not completely cut.

2. Description of the Prior Art

The current electronic products are developed toward a trend of multi-functions, and the key of developing the electronic products is the mature of the semiconductor technology, so that the chip with higher performance can be developed and widely used in the electronic products. When the chip is fabricated, dies are arranged on a wafer, and the dies should be cut and packaged to form the chip.

After the dies are formed on the wafer, the wafer must be test by a WAT (Wafer Acceptable Test, WAT) before it becomes a manufactured product. The main purpose of the WAT is to simulate the circuit designed by the customer and to monitor the stability of the manufacturing process and to enhance the product yield. Another important purpose of the WAT is to discover the problems on the production line by testing basic electrical parameters to judge whether an open circuit problem or a bridging problem occurs. Therefore, the WAT is regarded as the last defense line before the wafer becomes the manufactured product. The WAT is usually performed by using testkeys disposed on the cutting street of the wafer to process an electrical test to the wafer.

After the dies are tested, the wafer should be cut by a wafer die saw process to get dies and they are performed by a package process to form the chip. Theoretically, during the wafer die saw process, the testkey located on the wafer cutting street can be cut, and the chip can be normally operated. However, in practical applications, because of the size limitation of the cutting blade, the cutting blade with small width fails to cut all testkeys. On the other hand, because the development of the semiconductor manufacturing process, the number of the dies fabricated from a wafer increases to relatively shrink the size of the cutting street. As mentioned above, if a wider cutting blade is used, the testkey can be totally cut, but since the distance between the blade and the die becomes small, the die itself will be easily damaged.

For example, please refer to FIG. 1. FIG. 1 illustrates a schematic diagram of using a narrower cutting blade B to cut a wafer 1 in a prior art. As shown in FIG. 1, when the wafer 1 is cut, the width of the cutting blade B fails to totally cut a testkey 10, therefore, when a flip-chip thin film packaging process or a glass flip-chip packaging process is performed to the dies, the testkey 10 not cut will be bent to contact two signal leads to cause a short between the two signal leads, and the chip yield will be further affected, even the chip will be failed.

Therefore, a new type of testkey should be designed to prevent the short between the signal leads to affect the chip yield.

### SUMMARY OF THE INVENTION

A scope of the invention is to provide a testkey structure to solve the above-mentioned problems.

In an embodiment of the invention, the testkey structure is disposed near a chip and used for testing the chip. The testkey structure includes a metal pad and a groove. And, the groove is located between a first signal lead and a second signal lead of the chip.

In this embodiment, since the groove is located between the first signal lead and the second signal lead, the residual part of the metal pad formed after the metal pad is cut by a cutting blade will be separated by the groove. When the chip is packaged, the first signal lead and the second signal lead may contact the separated parts of the metal pad respectively, by doing so, the short occurred between the first signal lead and the second signal lead can be prevented.

Another scope of the invention is to provide a chip packaging structure, and its test pad can separate signal leads to prevent the signal leads from being short.

In an embodiment of the invention, the chip packaging structure includes a substrate, a chip, and a metal pad, wherein the chip and the metal pad are both disposed on the substrate, and the metal pad is located near the substrate. The metal pad has a first groove, and the first groove is located between a first signal lead and a second signal lead of the chip to separate the first signal lead and the second signal lead.

In this embodiment, since the first groove is located between the first signal lead and the second signal lead, when the chip is packaged, the first signal lead and the second signal lead may contact the separated sides of the metal pad respectively, by doing so, the short condition occurred between the first signal lead and the second signal lead can be prevented.

Another scope of the invention is to provide a testkey structure fabricating method to solve the above-mentioned problems.

In an embodiment of the invention, the testkey structure fabricating method is used for forming a testkey structure to test a chip and includes the steps of: disposing a metal pad on a cutting street of a substrate; disposing a first groove on the metal pad to form the testkey structure. The first groove extends from an edge of the metal pad to a central part of the metal pad.

In this embodiment, since the metal pad has the first groove, the residual part of the metal pad formed after the metal pad is cut by a cutting blade will be separated by the first groove. When the chip is packaged, the signal leads extending from the die may contact the separated parts of the metal pad respectively, by doing so, the short condition occurred between the signal leads can be prevented.

Another scope of the invention is to provide a chip packaging structure fabricating method to solve the above-mentioned problems.

In an embodiment of the invention, the chip packaging structure fabricating method is used to form a chip packaging structure and includes the steps of: disposing a metal pad on a cutting street of a substrate; disposing a first groove on the metal pad to form a testkey structure. The first groove extends from an edge of the metal pad to a central part of the metal pad.

In this embodiment, since the metal pad has the first groove, the residual part of the metal pad formed after the metal pad is cut by a cutting blade will be separated by the first groove. When the chip is packaged to form the chip packaging structure, the signal leads extending from the die may contact the separated parts of the metal pad respectively, by doing so, the short condition occurred between the signal leads can be prevented.

The advantage and spirit of the invention may be understood by the following recitations together with the appended drawings.

### BRIEF DESCRIPTION OF THE APPENDED DRAWINGS

FIG. 1 illustrates a schematic diagram of using a narrower cutting blade to cut a wafer in a prior art.

FIG. 2A illustrates a schematic diagram of the testkey structure in an embodiment of the invention.

FIG. 2B illustrates a schematic diagram of the substrate of FIG. 2A being cut by the cutting blade.

FIG. 2C illustrates a schematic diagram of the substrate of FIG. 2B being cut by the cutting blade.

FIG. 2D illustrates a schematic diagram of wiring the substrate of FIG. 2C after the substrate is cut.

FIG. 3 illustrates a schematic diagram of the wired die in another embodiment of the invention.

FIG. 4 illustrates a flowchart of the testkey structure fabricating method in another embodiment of the invention.

FIG. 5 illustrates a flowchart of the chip packaging structure fabricating method in another embodiment of the invention.

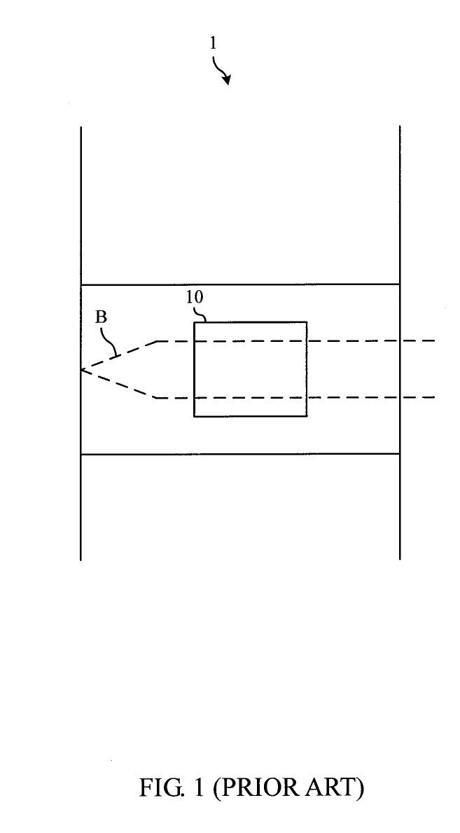

### DETAILED DESCRIPTION OF THE INVENTION

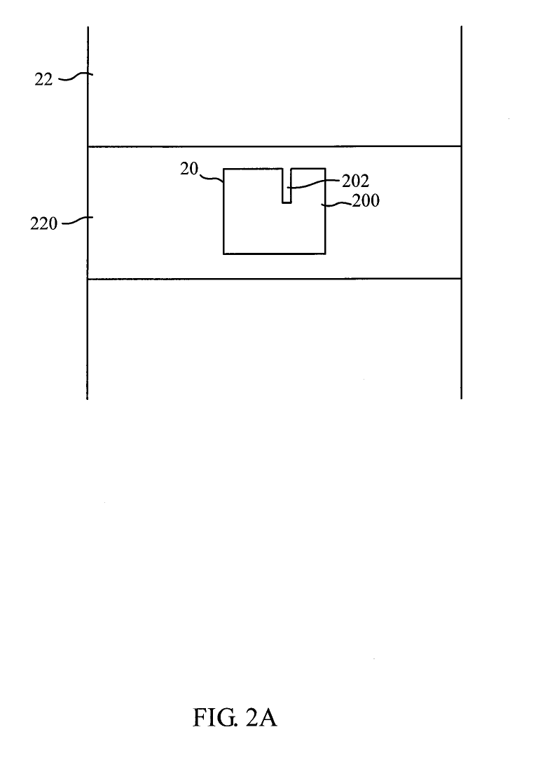

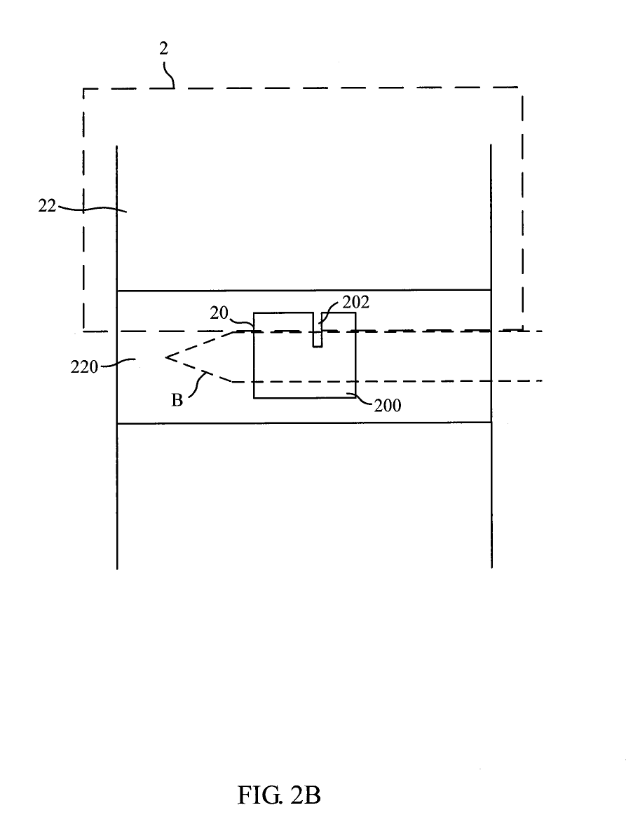

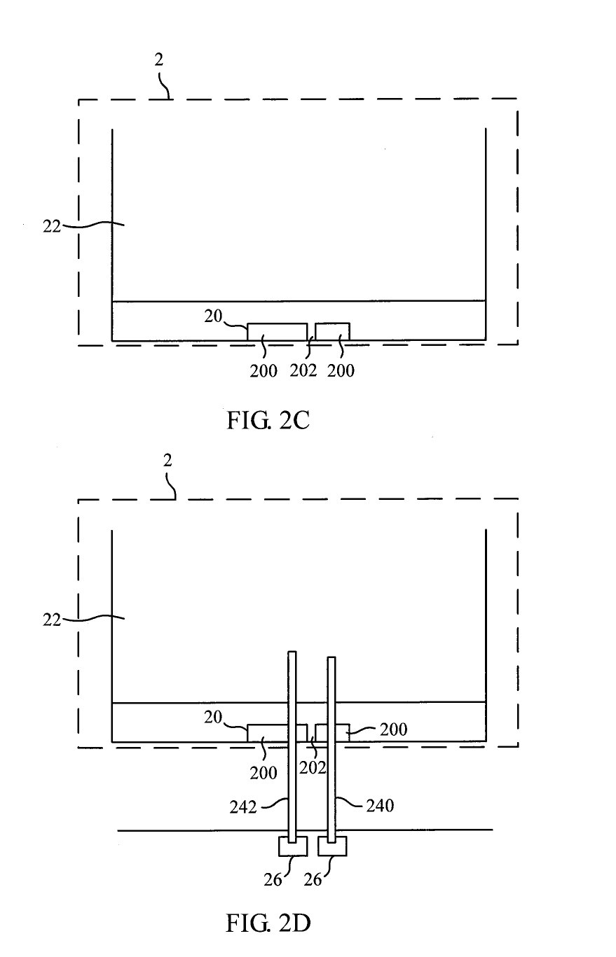

Please refer to FIG. 2A. FIG. 2A illustrates a schematic diagram of a testkey structure in an embodiment of the invention. As shown in FIG. 2A, the testkey structure 20 is disposed on a cutting street 220 of a substrate 22. The testkey structure 20 includes a metal pad 200 and a first groove 202, wherein the first groove 202 is disposed on the metal pad 200, and the first groove 202 extends from an edge of the metal pad 200 to a central part of the metal pad 200.

The testkey structure 20 can be used to test a chip. In this embodiment, the testkey structure 20 is used to test the chip disposed on the substrate 22 (not shown in the figure). In fact, a testing apparatus can connect to the testkey structure 20 and test the chip via the testkey structure 20 to obtain its parameters. Please notice that there is one testkey structure 20 used to test the chip, however, in practical applications, a plurality of testkey structures 20 can be used to test the chip, and since a wafer can include a plurality of chips, a corresponding amount of testkey structures 20 can be disposed on the cutting street of the substrate.

In this embodiment, the substrate 22 can be divided along the cutting street 220 to obtain dies. Please refer to FIG. 2B. FIG. 2B illustrates a schematic diagram of the substrate 22 of FIG. 2A being cut by the cutting blade B. As shown in FIG. 2B, the cutting blade B cuts the substrate 22 along the cutting street 220 of the substrate 22. Therefore, a part of the metal pad 200 and the first groove 202 will be cut by the cutting blade B, and the other part will be remained on the cutting street 220. In practical applications, the cut substrate 22 and the residual testkey structures 20 can be wired and packaged by a packaging glue to form a die 2, as shown in the circle of the dotted line of FIG. 2B.

Please refer to FIG. 2C. FIG. 2C illustrates a schematic diagram of the substrate 22 of FIG. 2B being cut by the cutting blade B. As shown in FIG. 2C, after the substrate 22 is cut, the metal pad 200 remained from the testkey structures 20 will be divided into two independent regions by the first groove 202. In other words, for the metal pad 200, the first groove 202 extends from the edge of the metal pad 200 to the central part before being cut; and after being cut, the first groove 202 extends from the edge of the metal pad 200 to another edge. In addition, please refer to FIG. 2D. FIG. 2D illustrates a schematic diagram of wiring the substrate 22 of FIG. 2C after the substrate 22 is cut. As shown in FIG. 2D, the die 2 is electrically connected to a bonding pad 26 via a first signal lead 240 and a second signal lead 242. In practical applications, after the wiring process is finished, the die 2 can be packaged by the packaging glue to form a chip packaging structure.

In the flip-chip thin film packaging process or the glass flip-chip packaging process, the testkey structures 20 is cut and the residual part may be bent to contact the first signal lead 240 and the second signal lead 242, as shown in FIG. 2D. Since a residual part of the metal pad 200 is divided by the first groove 202, and the first groove 202 is located between the first signal lead 240 and the second signal lead 242, therefore, when the first signal lead 240 and the second signal lead 242 contact with the residual part of the metal pad 200, the first groove 202 can effectively prevent the first signal lead 240 and the second signal lead 242 from forming a short condition through the residual part of the metal pad 200. By doing so, the chip yield can be enhanced.

In this embodiment, an extending direction of the first groove 202 on the metal pad 200 is substantially the same with extending directions of the first signal lead 240 and the second signal lead 242. Therefore, the first groove 202 can effectively divide the first groove 202 after being cut; therefore, an open circuit condition will be shown between the first signal lead 240 and the second signal lead 242 to prevent the short condition. In practical applications, the extending length of the first groove 202 extending from the edge depends on the width of the cutting blade B. The designing rule is to divide the metal pad 200 into two independent regions after being cut.

There is no limitation to this. For example, as to the driver of the LCD panel, the gap between the edge of the cutting blade and the edge of the metal pad is about 30˜40 μm. Therefore, considering the error, the first groove 202 can be designed that the first groove 202 extends 50 μm from the edge of the metal pad 202 to the central part.

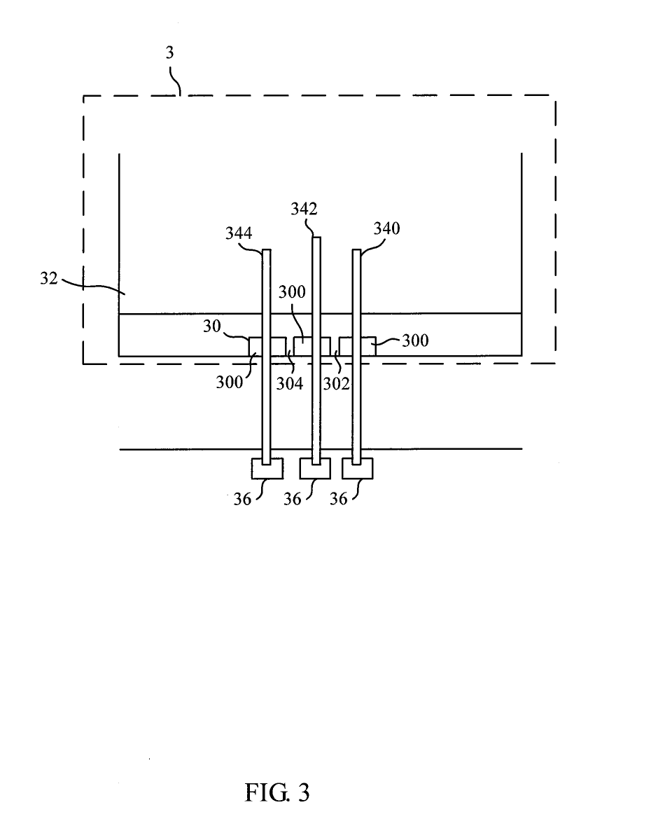

Please refer to FIG. 3. FIG. 3 illustrates a schematic diagram of a wired die 3 in another embodiment of the invention. As shown in FIG. 3, the die 3 includes a testkey structure 30 and a substrate 32, wherein the die 3 is electrically connected to bonding pads 36 via a first signal lead 340, a second signal lead 342, a third signal lead 344 respectively.

In this embodiment, the testkey structure 30 includes a metal pad 300 and a first groove 302 and a second groove 304 disposed on the metal pad 300. Please notice that the testkey structure 30 is the residual part after the die is cut. As shown in FIG. 3, the first groove 302 and the second groove 304 divide the metal pad 300 into three independent regions. When the die 3 is packaged, the three independent regions of the metal pad 300 may contact with a first signal lead 340, a second signal lead 342, and a third signal lead 344. Therefore, with the first groove 302 and the second groove 304, the first signal lead 340, the second signal lead 342, and the third signal lead 344 can be prevented from being contacted with the metal pad 300 to short, so that the yield of the chip can be enhanced.

In practical applications, the amount of grooves disposed on the metal pad is not limited by one or two in the above-mentioned embodiments and it is determined according to the amount of the die wirings passing the metal pad. For example, if the die has five signal leads passing above the metal pad, then there must be at least four grooves on the metal pad to divide the metal pad into five independent regions. Since the other units in this embodiment are substantially the same with the corresponding units in the above-mentioned embodiments, it is not described again here.

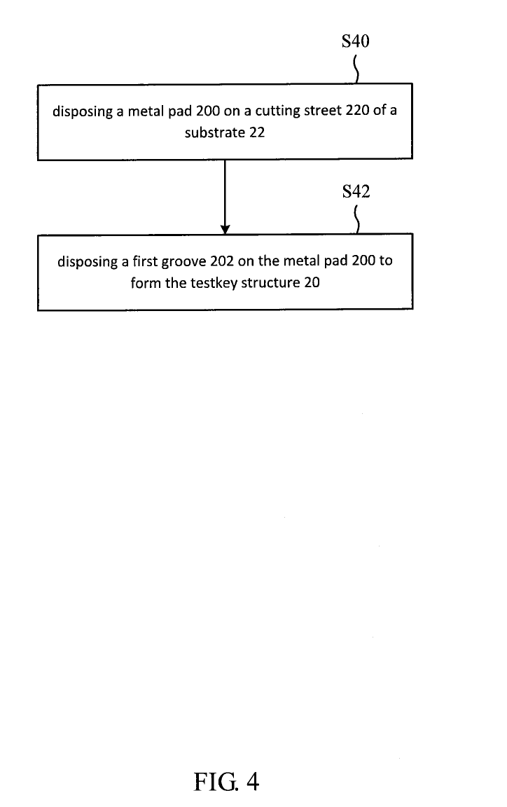

Please refer to FIG. 4 and FIG. 2A together, FIG. 4 illustrates a flowchart of the testkey structure fabricating method in another embodiment of the invention. As shown in FIG. 4 and FIG. 2A, the testkey structure fabricating method can used to form the testkey structure 20 to test a chip. The testkey structure fabricating method shown in FIG. 4 includes the following steps. In step S40, disposing a metal pad 200 on a cutting street 220 of a substrate 22; in step S42, disposing a first groove 202 on the metal pad 200 to form the testkey structure 20. In this embodiment, the first groove 202 formed in step S42 extends from an edge of the metal pad 200 to a central part of the metal pad 200.

In fact, the metal pad forming step S40 can use the ordinary methods used in semiconductor processes, such as gas phase deposition method or sputtering deposition method, to form a metal pad on the cutting street, and then use the etching method to complete the metal pad. In addition, the first groove in the step S42 can be also formed on the metal pad by the etching method. It should be noticed that the first groove can be formed by etching after the metal pad is done, or when the metal pas is formed, the position of the first groove is set by the exposure and developing method and the first groove is etched at the same time. In other words, the step S40 and the step S42 in this embodiment can be performed in order or at the same time, there is no limitation about this.

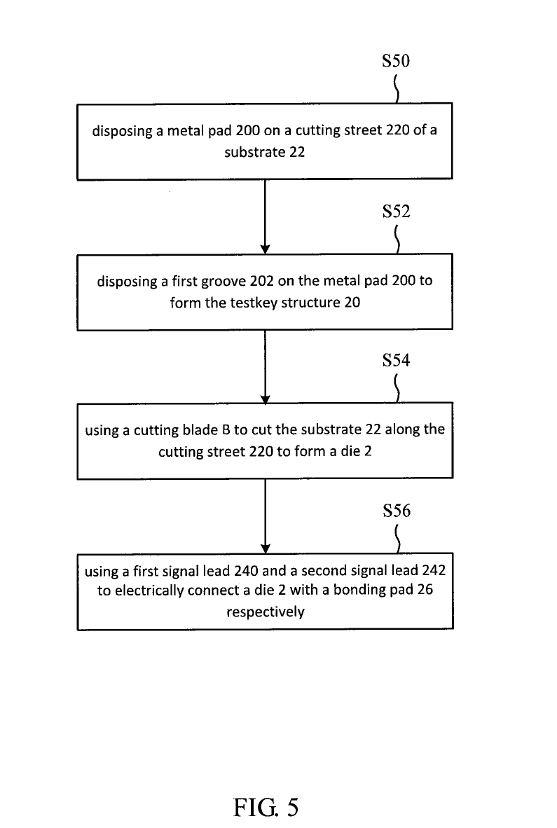

Please refer to FIG. 5, FIG. 2B, and FIG. 2D together. FIG. 5 illustrates a flowchart of the chip packaging structure fabricating method in another embodiment of the invention. As shown in FIG. 5, the difference between this embodiment and the previous embodiment is that the chip packaging structure fabricating method of this embodiment further includes the following steps. In the step S54, using a cutting blade B to cut the substrate 22 along the cutting street 220 to form a die 2; then, in the step S56, using a first signal lead 240 and a second signal lead 242 to electrically connect a die 2 with a bonding pad 26 respectively. In this embodiment, the first signal lead 240 and the second signal lead 242 in the step S56 are disposed at the two sides of the groove 202. Since the other steps in this embodiment are substantially the same with the corresponding steps in the above-mentioned embodiments, it is not described again here.

In this embodiment, when the step S54 uses a cutting blade B to cut the substrate 22 along the cutting street 220, a part of the testkey pad structure 20 will be remained, and the first groove 202 can divide the metal pad 200 into two independent regions. Since the first signal lead 240 and the second signal lead 242 in the step S56 are disposed at the two sides of the groove 202, namely the two independent regions of the residual metal pad 200 after being divided, therefore, when the die 2 fabricated by this chip packaging structure fabricating method is packaged with a packaging glue, the metal pad 200 may be bent and contact with the first signal lead 240 and the second signal lead 242, and the first signal lead 240 and the second signal lead 242 will be blocked by the first groove 202, so that the first signal lead 240 and the second signal lead 242 will not contact with the metal pad 200 to be short.

Compared to the prior arts, a groove is disposed on the testkey structure of the invention and the groove can divide the residual metal pad of the testkey structure into independent regions after the die is cut. When the die using this testkey structure is packaged, for example, by a flip-chip thin film packaging or a glass flip-chip packaging, the signal leads can be separated by the grooves to prevent the signal leads from contacting with the residual metal pad to be short. By doing so, the chip yield can be enhanced. On the other hand, because when the groove of the metal pad is formed, the groove extends from the edge of the metal pad to the central part, the metal pad is not divided by the groove; therefore, in the chip testing stage, the existence of the groove will not affect the chip testing result.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A testkey structure, disposed near a chip and used for testing the chip, the testkey structure comprising:
a metal pad; and
a first groove, disposed on the metal pad;
wherein the first groove is located between a first signal lead and a second signal lead of the chip to separate the first signal lead and the second signal lead.

2. The testkey structure of claim 1, wherein the first groove extends from an edge of the metal pad to a central part of the metal pad.

3. The testkey structure of claim 1, further comprising a second groove disposed on the metal pad, and the second groove is located between the second signal lead and a third signal lead of the chip to separate the second signal lead and the third signal lead.

4. The testkey structure of claim 3, wherein the second groove extends from an edge of the metal pad to a central part of the metal pad.

5. The testkey structure of claim 1, wherein an extending direction of the first groove is substantially the same with extending directions of the first signal lead and the second signal lead.

6. A chip packaging structure, comprising:
a substrate;
a chip, disposed on the substrate;
a first signal lead, coupled to the chip;
a second signal lead, coupled to the chip; and
a metal pad, disposed on the substrate and near the chip, the metal pad having a first groove;
wherein the first groove is located between the first signal lead and the second signal lead to separate the first signal lead and the second signal lead.

7. The chip packaging structure of claim 6, wherein the first groove extends from a first edge of the metal pad to a second edge of the metal pad.

8. The chip packaging structure of claim 6, further comprising a third signal lead coupled to the chip, and the metal pad further comprising a second groove located between the second signal lead and the third signal lead to separate the second signal lead and the third signal lead.

9. The chip packaging structure of claim 8, wherein the second groove extends from a first edge of the metal pad to a second edge of the metal pad.

10. The chip packaging structure of claim 6, wherein an extending direction of the first groove is substantially the same with extending directions of the first signal lead and the second signal lead.

11. The chip packaging structure of claim 6, further comprising a first bonding pad and a second bonding pad, the first signal lead and the second signal lead are electrically connected to the first bonding pad and the second bonding pad respectively.

12. The chip packaging structure of claim 6, wherein the chip packaging structure is a flip-chip thin film packaging structure.

13. The chip packaging structure of claim 6, wherein the chip packaging structure is a glass flip-chip packaging structure.

14. A testkey structure fabricating method, used for forming a testkey structure to test a chip, the method comprising the steps of:
disposing a metal pad on a cutting street of a substrate; and
disposing a first groove on the metal pad to form the testkey structure;
wherein the first groove extends from an edge of the metal pad to a central part of the metal pad.

15. A chip packaging structure fabricating method, used for fabricating a chip packaging structure, the method comprising the steps of:
disposing a metal pad on a cutting street of a substrate; and
disposing a first groove on the metal pad;
wherein the first groove extends from an edge of the metal pad to a central part of the metal pad.

16. The method of claim 15, further comprising the steps of:
using a cutting blade to cut the substrate along the cutting street; and
using a first signal lead and a second signal lead to electrically connect a die on the substrate with a first bonding pad and a second bonding pad;
wherein the first signal lead and the second signal lead are located at two sides of the first groove and separated by the first groove.
